(19) United States
(12) Patent Application Publication
(10) Pub. No.: US 2025/0289922 A1
(43) Pub. Date: Sep. 18, 2025

(54) EPOXY RESIN COMPOSITION FOR ENCAPSULATING SEMICONDUCTOR DEVICE AND SEMICONDUCTOR DEVICE ENCAPSULATED USING THE SAME

(71) Applicant: SAMSUNG SDI CO., LTD., Yongin-si (KR)

(72) Inventors: Dong Hwan LEE, Suwon-si (KR); Ki Hyeok KWON, Suwon-si (KR); Young Joon LEE, Suwon-si (KR); Young Ho KIM, Suwon-si (KR); Yong Han CHO, Suwon-si (KR); Tae Shin EOM, Suwon-si (KR)

(21) Appl. No.: 19/077,390

(22) Filed: Mar. 12, 2025

(30) Foreign Application Priority Data
Mar. 13, 2024 (KR) 10-2024-0035274

(51) Int. Cl. C08G 59/22; C08G 59/42; C08G 59/68; C08K 3/04; C08K 3/22; C08K 5/20; C08K 5/5419; C08K 5/544; C08K 7/18

(52) U.S. Cl. CPC C08G 59/22; C08G 59/4269; C08G 59/688; C08K 5/20; C08K 7/18; C08K 3/04; C08K 2003/2227; C08K 5/5419; C08K 5/544; C08K 2201/005; C08K 2201/014

(57) ABSTRACT

An epoxy resin composition for encapsulation of semiconductor devices and a semiconductor device encapsulated using the epoxy resin composition, the epoxy resin composition including an epoxy resin, a curing agent, an inorganic filler, a curing catalyst, and an additive including at least one compound represented by Formula 1,

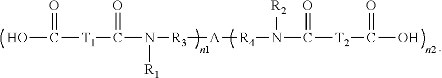

### CROSS-REFERENCE TO RELATED APPLICATION

The present application claims priority and the benefit of Korean Patent Application No. 10-2024-0035274, filed on Mar. 13, 2024 in the Korean Intellectual Property Office, the entire disclosure of which is incorporated herein by reference.

### BACKGROUND

### 1. Field

Embodiments relate to an epoxy resin composition for encapsulation of semiconductor devices and a semiconductor device encapsulated using the same.

### 2. Description of the Related Art

As electronic devices continue to become smaller, lighter, and more high-performance, integration of semiconductors is accelerating every year. With increasing demand for surface mounting of semiconductor devices, problems that cannot be solved by conventional epoxy resin compositions have occurred. Low shrinkage and low elasticity properties are required to prevent problems, such as warpage of a package due to differential thermal expansion and contraction between a substrate and the epoxy resin composition, breakage or failure of semiconductor chips due to high elasticity of a cured product of the composition, and the like.

### SUMMARY

Embodiments are directed to an epoxy resin composition for encapsulation of semiconductor devices, the epoxy resin composition including an epoxy resin, a curing agent, an inorganic filler, a curing catalyst, and an additive including at least one compound represented by Formula 1:

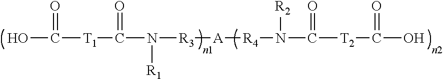

wherein A is a substituted or unsubstituted C₃ to C₂₀ cycloalkylene group or a substituted or unsubstituted C₆ to C₂₀ arylene group, R₁ and R₂ are each independently hydrogen or a substituted or unsubstituted C₁ to C₅ alkyl group, R₃ and R₄ are each independently a single bond or a substituted or unsubstituted C₁ to C₅ alkylene group, T₁ and T₂ are each independently a substituted or unsubstituted C₁ to C₁₀ alkylene group, and n1 and n2 are each independently an integer of greater than or equal to 1.

The at least one compound represented by Formula 1 may be included in the epoxy resin composition in an amount of 0.5 wt % to 5 wt %, based on a total amount of the epoxy resin composition.

The additive including at least one compound represented by Formula 1 may include at least one compound represented by Formula 2 or Formula 3,

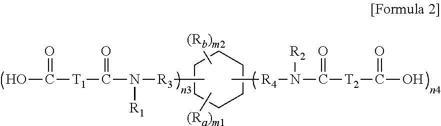

wherein each of R₁, R₂, R₃, R₄, T₁, and T₂ may be defined the same as those of Formula 1 Rₐ and R_{b} may each independently be a substituted or unsubstituted C₁ to C₁₀ alkyl group or a substituted or unsubstituted C₆ to C₁₀ aryl group, n3 and n4 may each independently be an integer of greater than or equal to 1, and m1 and m2 may each independently be an integer of greater than or equal to 0,

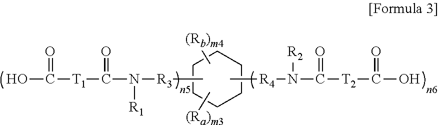

wherein each of R₁, R₂, R₃, R₄, T₁, and T₂ may be defined the same as those of Formula 1, Rₐ and R_{b} may each independently be a substituted or unsubstituted C₁ to C₁₀ alkyl group or a substituted or unsubstituted C₆ to C₁₀ aryl group, n5 and n6 may each independently be an integer of greater than or equal to 1, and m3 and m4 may each independently be an integer of greater than or equal to 0.

The additive including at least one compound represented by Formula 1 may include at least one compound represented by Formula 4 to Formula 7,

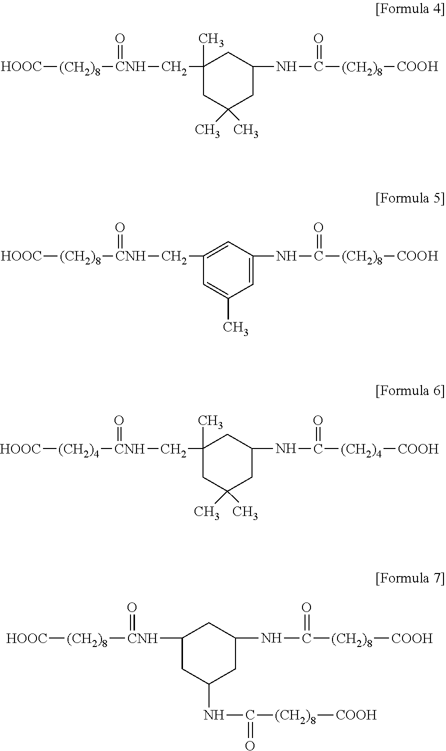

The epoxy resin composition may include, based on a total weight of the epoxy resin composition, 2 wt % to 17 wt % of the epoxy resin, 0.5 wt % to 13 wt % of the curing agent, 50 wt % to 95 wt % of the inorganic filler, 0.5 wt % to 5 wt % of the at least one compound represented by Formula 1, and 0.01 wt % to 5 wt % of the curing catalyst.

The embodiments may be realized by providing a semiconductor device encapsulated using the epoxy resin composition according to some embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout. As used herein, the term “or” is not an exclusive term, e.g., “A or B” would include A, B, or A and B.

As used herein to represent a specific numerical range, “X to Y” means “greater than or equal to X and less than or equal to Y”.

As used herein, the term “substituted” in the expression “substituted or unsubstituted” means that at least one hydrogen atom of a corresponding functional group is substituted with a hydroxyl group, an amino group, a nitro group, a cyano group, a C₁ to C₂₀ alkyl group, a C₁ to C₂₀ haloalkyl group, a C₆ to C₃₀ aryl group, a C₃ to C₃₀ heteroaryl group, a C₃ to C₁₀ cycloalkyl group, a C₃ to C₁₀ heterocycloalkyl group, a C₇ to C₃₀ arylalkyl group, or a C₁ to C₃₀ heteroalkyl group.

Herein, “cycloalkylene group” refers to a chemical group obtained by removing one or more hydrogen atoms from a monocyclic or polycyclic C₃ to C₂₀ compound containing one or more cycloalkyl groups or a derivative thereof. For example, a cycloalkylene group may include a cyclohexylene group or a cyclopentylene group.

Herein, “arylene group” refers to a chemical group obtained by removing two or more hydrogen atoms from a monocyclic or polycyclic C₆ to C₂₀ compound containing one or more benzene rings or a derivative thereof. For example, the benzene ring-containing monocyclic or polycyclic compound may include a toluene or xylene compound in which an alkyl side chain is attached to a benzene ring, a biphenyl compound in which two or more benzene rings are bonded through a single bond, a fluorene, xanthene, or anthraquinone compound in which a benzene ring is condensed with a cycloalkyl group or a heterocycloalkyl group, a naphthalene or anthracene compound in which two or more benzene rings are condensed with each other, and the like.

In accordance with one aspect of the present disclosure, an epoxy resin composition may include an additive including at least one compound represented by

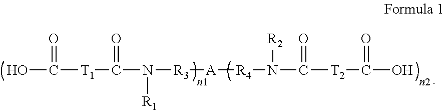

In Formula 1, A may be or include, e.g., a substituted or unsubstituted C₃ to C₂₀ cycloalkylene group or a substituted or unsubstituted C₆ to C₂₀ arylene group.

R₁ and R₂ may each independently be or include, e.g., hydrogen or a substituted or unsubstituted C₁ to C₅ alkyl group.

R₃ and R₄ may each independently be or include, e.g., a single bond or a substituted or unsubstituted C₁ to C₅ alkylene group.

T₁ and T₂ may each independently be or include, e.g., a substituted or unsubstituted C₁ to C₁₀ alkylene group.

n1 and n2 may each independently be or include, e.g., an integer of greater than or equal to 1.

An epoxy resin composition with a high content of inorganic filler may have low toughness after curing, despite having low cure shrinkage and low coefficient of thermal expansion. Low toughness of the composition may cause breakage and cracking of a semiconductor if the semiconductor is subjected to external shock or reliability testing. If used in an epoxy resin composition with a high content of inorganic filler, the additive including at least one compound represented by Formula 1 may help improve crack resistance and stiffness of the composition by significantly increasing toughness of the composition. In an implementation, the additive including at least one compound represented by Formula 1 may help provide the effects described above without sacrificing low cure shrinkage, low coefficient of thermal expansion, and high modulus of the composition due to the high content of inorganic filler.

The at least one compound represented by Formula 1 may be, e.g., an amide compound containing two or more terminal carboxylic acid groups and may help increase toughness of the epoxy resin composition after curing.

In one embodiment, in Formula 1, A may be, e.g., a substituted or unsubstituted C₃ to C₁₀ cycloalkylene group or a substituted or unsubstituted C₆ to C₁₀ arylene group. In an implementation, in Formula 1, A may be, e.g., a substituted or unsubstituted cyclopentylene group, a substituted or unsubstituted cyclohexylene group, a substituted or unsubstituted phenylene group, or a substituted or unsubstituted naphthalene group.

In one embodiment, in Formula 1, T₁ and T₂ may each independently be, e.g., a substituted or unsubstituted C₃ to C₈ alkylene group or a substituted or unsubstituted C₄ to C₈ alkylene group.

In one embodiment, in Formula 1, R₃ and R₄ may be identical to each other or different from each other and may each independently be, e.g., a single bond or a substituted or unsubstituted C₁ to C₃ alkylene group. Here, “single bond” may refer to a direct chemical bond between A and nitrogen (N) in Formula 1.

In one embodiment, in Formula 1, R1 and R2 may be identical to each other or different from each other and may each independently be, e.g., hydrogen or a substituted or unsubstituted C₁ to C₃ alkyl group, e.g., hydrogen.

In one embodiment, in Formula 1, n1 and n2 may be equal to each other or different from each other and each may independently be, e.g., an integer of 1 to 5 or an integer of 1 to 3.

The additive including at least one compound represented by Formula 1 may include at least one compound represented by Formula 2 or Formula 3.

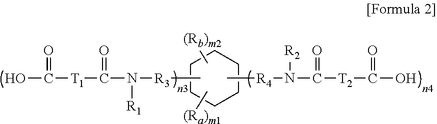

In Formula 2, each of R₁, R₂, R₃, R₄, T₁, and T₂ may be defined the same as those of Formula 1,

Rₐ and R_{b} may each independently be, e.g., a substituted or unsubstituted C₁ to C₁₀ alkyl group or a substituted or unsubstituted C₆ to C₁₀ aryl group. n3 and n4 may each independently be, e.g., an integer of greater than or equal to 1.

m1 and m2 may each independently be, e.g., an integer of greater than or equal to 0.

In one embodiment, each of Rₐ and R_{b} may be, e.g., a substituted or

unsubstituted C₁ to C₅ alkyl group.

In one embodiment, n3 and n4 may each independently be, e.g., an integer of 1 to 11 or an integer of 1 to 6.

In one embodiment, m1 and m2 may each independently be, e.g., an integer 0 to 10 or an integer of 0 to 6.

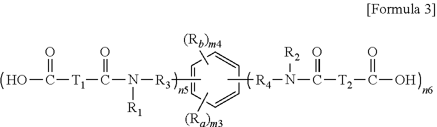

In Formula 3, each of R₁, R₂, R₃, R₄, T₁, and T₂ may be defined the same as those of Formula 1.

Rₐ and R_{b} may each independently be, e.g., a substituted or unsubstituted C₁ to C₁₀ alkyl group or a substituted or unsubstituted C₆ to C₁₀ aryl group. n5 and n6 may each independently be, e.g. an integer of greater than or equal to 1.

m3 and m4 may each independently be, e.g., an integer of greater than or equal to 0.

In one embodiment, each of Rₐ and R_{b} may independently be, e.g., a C₁ to C₅ alkyl group.

In one embodiment, n5 and n6 may each independently be, e.g., an integer of 1 to 5 or an integer of 1 to 3.

In one embodiment, m3 and m4 may be each independently be, e.g., an integer of 0 to 4 or an integer of 0 to 2.

In an implementation, the additive including at least one compound represented by Formula 1 may include at least one compound represented by Formula 4 to Formula 7.

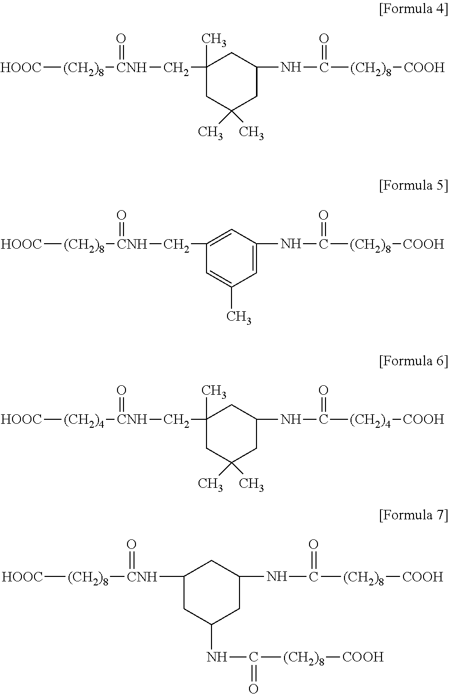

The epoxy resin composition may include one or more types of compounds represented by Formula 1.

The at least one compound represented by Formula 1 may be included in the epoxy resin composition in an amount of 0.5 wt % to 5 wt %, based on a total weight of the in the epoxy resin composition. Maintaining the at least one compound represented by Formula 1 within this range may help ensure that the at least one compound represented by Formula 1 may help increase toughness of the composition. In an implementation, the at least one compound represented by Formula 1 may be included in the epoxy resin composition in an amount of 0.8 wt % to 3 wt %, based on the total weight of the epoxy resin composition.

The epoxy resin composition may further include, e.g., an epoxy resin, a curing agent, an inorganic filler, and a curing catalyst.

### Epoxy Resin

The epoxy resin may be, e.g., an epoxy resin containing at least two epoxy groups in a molecular structure thereof and may include, e.g., bisphenol A epoxy resins, bisphenol F epoxy resins, phenol novolac epoxy resins, tert-butyl catechol epoxy resins, naphthalene epoxy resins, glycidyl amine epoxy resins, cresol novolac epoxy resins, biphenyl epoxy resins, phenol aralkyl epoxy resins, linear aliphatic epoxy resins, cycloaliphatic epoxy resins, heterocyclic epoxy resins, spirocyclic epoxy resins, cyclohexanedimethanol epoxy resins, trimethylol epoxy resins, halogenated epoxy resins, or the like. In an implementation, the epoxy resin may include, e.g., a biphenyl epoxy resin or a phenol aralkyl epoxy resin. These epoxy resins may be used alone or as a mixture thereof.

The epoxy resin may be included in the epoxy resin composition in an amount of 2 wt % to 17 wt %, e.g., 2 wt % to 10 wt %, based on the total weight of the epoxy resin composition. Maintaining the amount of epoxy resin within these ranges may help ensure that the composition can avoid reduction in curability.

### Curing Agent

The curing agent may include, e.g., polyfunctional phenol resins including aralkyl-type phenol resins, novolac-type phenol resins, Xylok-type phenol resins, cresol novolac-type phenol resins, naphthol-type phenol resins, terpene-type phenol resins, dicyclopentadiene phenol resins, novolac-type phenol resins synthesized from bisphenol A or resol, or the like, polyhydric phenol compounds including, e.g., tris(hydroxyphenyl) methane, dihydroxybiphenyl, or the like, acid anhydrides including, e.g., maleic anhydride, phthalic anhydride, or the like, and aromatic amines including, e.g., metaphenylenediamine, diaminodiphenylmethane, diaminodiphenylsulfone, or the like. In an implementation, the curing agent may include, e.g., a Xylok-type phenol resin or an aralkyl-type phenol resin.

The curing agent may be included in the epoxy resin composition in an amount of 0.5 wt % to 13 wt %, based on the total weight of epoxy resin composition. Maintaining the amount of curing agent within this range may help ensure that the composition may avoid reduction in curability.

### Inorganic Filler

The inorganic filler may serve to help improve mechanical properties of the epoxy resin composition while helping reduce the internal stress of the epoxy resin composition.

The inorganic filler may include, e.g., fused silica, crystalline silica, calcium carbonate, magnesium carbonate, alumina, magnesia, clay, talc, calcium silicate, titanium oxide, antimony oxide, or glass fiber.

In an implementation, the inorganic filler may include, e.g., fused silica having a low coefficient of linear expansion to reduce internal stress of the epoxy resin composition. Here, fused silica may refer to, e.g., amorphous silica having a true specific gravity of 2.3 or less and may include amorphous silica that is prepared by melting crystalline silica or may be synthesized from various raw materials. In an implementation, it may be desirable that a fused silica mixture including 50 wt % to 99 wt % of spherical fused silica having an average particle diameter of 5 μm to 30 μm and 1 wt % to 50 wt % of spherical fused silica having an average particle diameter of 0.001 μm to 1 μm, based on a total amount of fused silica, be included in the inorganic filler in an amount of 40 wt % to 100 wt %, based on a total weight of the inorganic filler. In an implementation, the maximum particle diameter of the fused silica may be, e.g., adjusted to any one of 45 μm, 55 μm, or 75 μm, depending on the intended applications thereof.

The content of the inorganic filler in the composition may be varied depending on properties required for the composition, e.g., thermal conductivity, moldability, low stress, or strength at high temperatures. In some embodiments, the inorganic filler may be included in the epoxy resin composition in an amount of 50 wt % to 95 wt %, e.g., 70 wt % to 95 wt % or 85 wt % to 95 wt %, based on the total weight of the epoxy resin composition. Maintaing the amount of the inorganic filler in these ranges may help ensure that the epoxy resin composition may have good properties in terms of flame retardancy, fluidity, and reliability.

### Curing Catalyst

The curing catalyst may include, e.g., a tertiary amine compound, an organometallic compound, an organophosphorus compound, an imidazole compound, or a boron compound. The tertiary amine compound may include, e.g., benzyldimethylamine, triethanolamine, triethylenediamine, diethylaminoethanol, tri(dimethylaminomethyl) phenol, 2,2-(dimethylaminomethyl)phenol, 2,4,6-tris(diaminomethyl)phenol, tri-2-ethyl hexanoate, or the like. The organometallic compound may include, e.g., chromium acetylacetonate, zinc acetylacetonate, nickel acetylacetonate, or the like. The organophosphorus compound may include, e.g., triphenylphosphine, tris-4-methoxyphosphine, triphenylphosphine-triphenylborane, a triphenylphosphine-1,4-benzoquinone adduct, or the like. The imidazole compound may include, e.g., 2-methylimidazole, 2-phenylimidazole, 2-aminoimidazole, 2-methyl-1-vinylimidazole, 2-ethyl-4-methylimidazole, 2-heptadecyl imidazole, or the like. The boron compound may include, e.g., triphenylphosphine tetraphenyl borate, a tetraphenylboron salt, trifluoroborane-n-hexylamine, trifluoroborane monoethylamine, tetrafluoroborane triethylamine, tetrafluoroborane amine, or the like. In an implementation, 1,5-diazabicyclo[4.3.0]non-5-ene (DBN), 1,8-diazabicyclo[5.4.0]undec-7-ene (DBU), or a phenol novolac resin salt may be used as the curing catalyst.

The curing catalyst may be included, e.g., in the form of an adduct prepared by pre-reacting the curing catalyst with the epoxy resin or the curing agent.

The curing catalyst may be included in the epoxy resin composition, e.g., in an amount of 0.01 wt % to 5 wt %, based on the total weight of the epoxy resin composition. Maintaining the amount of the curing catalyst in this range may help ensure that the curing catalyst may help promote curing of the composition without sacrificing fluidity of the composition.

The epoxy resin composition may further include suitable additives used in epoxy resin compositions for encapsulation of semiconductor devices. In some embodiments, the additives may include, e.g., a coupling agent, a release agent, a colorant, a stress relieving agent, a crosslinking enhancer, or a leveling agent.

The coupling agent may serve to increase interfacial strength between the epoxy resin and the inorganic filler through reaction with the epoxy resin and the inorganic filler and may include, e.g., a silane coupling agent. The silane coupling agent may include any silane coupling agent that may increase interfacial strength between the epoxy resin and the inorganic filler through reaction with the epoxy resin and the inorganic filler. The silane coupling agent may include, e.g., epoxy silane, amino silane, ureido silane, mercapto silane, alkyl silane, or the like. These coupling agents may be used alone or in combination thereof. The coupling agent may be included in the epoxy resin composition in an amount of 0.01 wt % to 5 wt %, e.g., 0.05 wt % to 3 wt %, based on the total weight of the epoxy resin composition. Maintaining the amount of coupling agent within these ranges may help ensure that a cured product of the epoxy resin composition may have enhanced strength.

The release agent may include, e.g., paraffin wax, ester wax, higher fatty acids, metallic salts of higher fatty acids, natural fatty acids, and metallic salts of natural fatty acids. The release agent may be included in the epoxy resin composition an amount of 0.1 wt % to 1 wt %, based on the total weight of the epoxy resin composition.

The colorant may include, e.g., carbon black. The colorant may be included in the epoxy resin composition in an amount of 0.1 wt % to 1 wt %, based on the total weight of the epoxy resin composition.

The stress relieving agent may include, e.g., modified silicone oils, silicone elastomers, silicone powders, and silicone resins. The stress relieving agent may be included in the epoxy resin composition in an amount of 2 wt % or less, e.g., 1 wt % or less or 0.1 wt % to 1 wt %, based on the total weight of the epoxy resin composition.

The additives may be included in the epoxy resin composition in an amount of 0.1 wt % to 5 wt %, e.g., 0.1 wt % to 3 wt %, based on the total weight of the epoxy resin composition.

The epoxy resin composition may be prepared, e.g., by uniformly mixing the aforementioned components in a Henschel mixer or a Lödige mixer, melt-kneading the mixture in a roll mill or a kneader at, e.g., 90° C. to 120° C., and subjecting the resulting product to cooling and pulverization.

In accordance with another aspect of the present disclosure, a semiconductor device may be encapsulated using the epoxy resin composition for encapsulation of semiconductor devices according to an embodiment. The semiconductor device may be encapsulated with the epoxy resin composition by any suitable method, such as transfer molding, injection molding, casting, or compression molding. In one embodiment, the semiconductor device may be encapsulated with the epoxy resin composition by low-pressure transfer molding. In another embodiment, the semiconductor device may be encapsulated with the epoxy resin composition by compression molding.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Preparative Example 1: Preparation of Compound Represented by Formula 4

The compound represented by Formula 4 was prepared according to Reaction

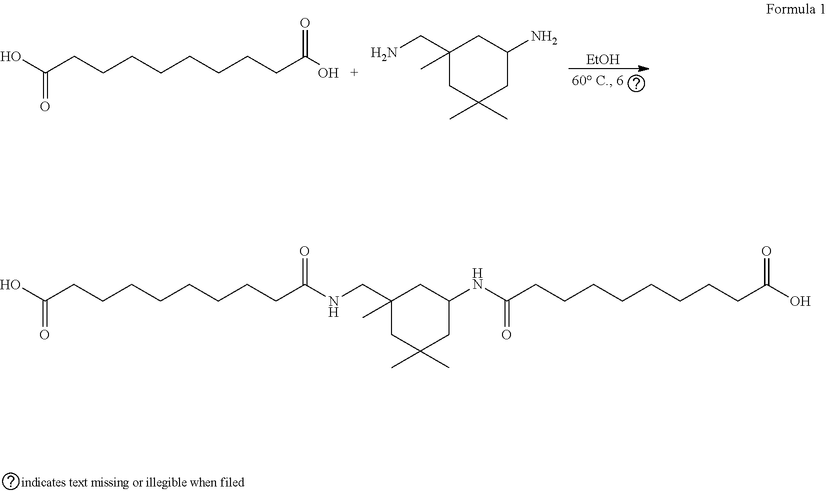 [SMILES: "EtOH" ; O=C(O)CCCCCCCCC(=O)O ; CC1(C)CC(N)CC(C)(CN)C1 ; CC1(C)CC(NC(=O)CCCCCCCCC(=O)O)CC(C)(CNC(=O)CCCCCCCCC(=O)O)C1]

Sebacic acid (40.4 g, 2 equivalents), isophoronediamine (15.6 g, 1 equivalent), and 200 ml of ethanol were placed in a round bottom flask and stirred at 60° C. for 6 hours. The obtained reaction mixture was cooled to ambient temperature and then distilled under vacuum (pressure: 15 mbar, temperature: 40° C.) to remove remaining ethanol, thereby obtaining 50.1 g of the compound represented by Formula 4 at a yield of 94%. NMR confirmed that the resulting product was the compound represented by Formula 4.

¹H NMR (400 MHZ, CDCl₃) 4.43; (t, 1H), 3.41; (br. s, 2H), 2.77; (br. s, 4H), 2.55; (t, 4H), 1.68-1.98; (m, 10H), 1.30-1.56; (m, 19H), 1.23-1.30; (m, 4H), 1.20; (br. s, 3H), 1.08; (br. s, 3H) ppm; ¹³C NMR (100 MHZ, CDCl₃) 177.3, 172.4, 172.2, 49.1, 48.1 45.1, 43.0, 36.8, 36.5, 36.1, 29.4, 29.2, 29.1, 29.0, 28.7, 28.6, 27.9, 27.8, 25.7, 24.8, 24.6, 22.8, 22.4, 18.3 ppm; LC-MS m/z=539 (M⁺); Anal. Calcd for C₃₀H₅₄N₂O₆: C, 66.88; H, 10.10; N, 5.20; Found: C, 66.49; H, 10.17; N, 5.33.

### Preparative Example 2: Preparation of Compound Represented by Formula 5

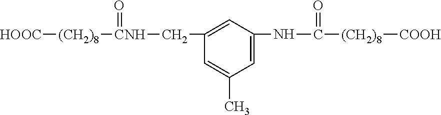

Sebacic acid (300 mmol, 2 equivalents), 3-amino-5-methylbenzenemethanamine (13.6 g, 1 equivalent), and 200 ml of ethanol were placed in a round bottom flask and stirred at 60° C. for 6 hours. The obtained reaction mixture was cooled to ambient temperature and then distilled under vacuum (pressure: 15 mbar, temperature: 40° C.) to remove remaining ethanol, thereby obtaining 47.8 g of the compound represented by Formula 5 at a yield of 95%. NMR confirmed that the resulting product was the compound represented by Formula 5. ¹H NMR (400 MHZ, CDCl₃) 11.1; (br. s, 2H), 7.81; (br s, 2H), 7.25; (s, 1H), 7.20; (s, 1H), 6.60; (s, 1H), 4.46; (s, 2H), 2.35; (s, 3H), 2.23-2.18; (m, 8H), 1.67-1.56; (m, 8H), 1.30-128; (m, 16) ppm; ¹³C NMR (100 MHZ, CDCl₃) 177.3, 172.4, 172.2, 141.8, 138.4, 138.2, 124.4, 119.3, 116.2, 44.4, 36.5, 36.3, 36.1, 29.4, 29.2, 29.1, 28.7, 27.9, 25.7, 25.6, 24.9, 24.8, 24.6 ppm; LC-MS m/z=504.1 (M⁺); Anal. Calcd for C₂₈H₄₄N₂O₆: C, 66.64; H, 8.79; N, 5.51; Found: C, 66.58; H, 9.01; N, 5.84

### Preparative Example 3: Preparation of Compound Represented by Formula 6

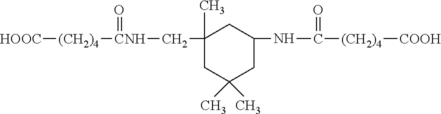

Adipic acid (30.0 g, 2 equivalents), isophoronediamine (15.6 g, 1 equivalent), and 200 ml of ethanol were placed in a round bottom flask and stirred at 60° C. for 6 hours. The obtained reaction mixture was cooled to ambient temperature and then distilled under vacuum (pressure: 15 mbar, temperature: 40° C.) to remove the remaining ethanol, thereby obtaining 35.4 g of the compound represented by Formula 6 at a yield of 83%. NMR confirmed that the resulting product was the compound represented by Formula 6. ¹H NMR (400 MHZ, CDCl₃) 11.1; (br. s, 2H), 7.81; (br s, 2H), 7.25 (s, 1H), 3.54; (m, 1H), 3.24; (m, 1H), 2.99; (m, 1H), 2.23-2.18; (m, 8H), 1.71-1.15; (m, 14H), 1.71-1.20; (m, 14H), 1.19; (br. s, 3H), 1.19; (s, 3H), 1.08; (br. s, 3H) ppm; ¹³C NMR (100 MHZ, CDCl₃) 177.3, 172.4, 49.1, 48.1, 45.0, 43.0, 37.4, 36.5, 36.2, 35.4, 27.9, 27.8, 25.1, 25.0, 23.8, 23.7, 22.8, 22.4, 18.3 ppm; LC-MS m/z=426.2 (M⁺); Anal. Calcd for C₂₂H₃₈N₂O₆: C, 61.95; H, 8.98; N, 6.57; Found: C, 61.59; H, 9.14; N, 6.35

### Preparative Example 4: Preparation of Compound Represented by Formula 7

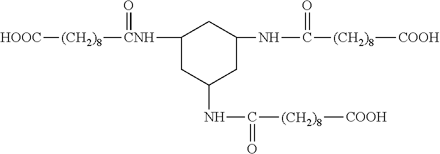

Sebacic acid (60.6 g, 3 equivalents), 1,3,5-cyclohexanetriamine (13.0 g, 1 equivalent), and 200 ml of ethanol were placed in a round bottom flask followed by stirring at 60° C. for 8 hours. The obtained reaction mixture was cooled to ambient temperature and then distilled under vacuum (pressure: 15 mbar, temperature: 40° C.) to remove remaining ethanol, thereby obtaining 50.1 g of the compound represented by Formula 7 at a yield of 94%. NMR confirmed that the resulting product was the compound represented by Formula 7. ¹H NMR (400 MHZ, CDCl₃) 11.1; (br s 3H), 7.9; (br s 3H), 3.54; (m, 3H), 2.20-2.17; (m, 12H), 2.01-1.75; (m, 6H), 1.58-1.55; (m, 12H), 1.30-1.25; (m, 24H) ppm; ¹³C NMR (100 MHZ, CDCl₃) 177.3, 172.4, 41.9, 36.8, 36.1, 29.4, 29.1, 29.0, 28.7, 25.7, 24.8 ppm; LC-MS m/z=681 (M⁺); Anal. Calcd for C₃₆H₆₃N₃O₉: C, 63.41; H, 9.31; N, 6.16; Found: C, 63.38; H, 9.46; N, 6.30.

Details of components used in the Examples and Comparative Examples were as follows:
(A) Epoxy resin: A phenol aralkyl epoxy resin (NC-3000, Nippon Kayaku Co., Ltd.)
(B) Curing agent: MEH-7851 (aralkyl-type phenol resin, Meiwa Corporation)
(C) Curing catalyst: Triphenyl phosphine (Hokko Chemical Co., Ltd.)
(D) Inorganic filler: A mixture of spherical fused alumina having an average particle diameter (D₅₀) of 20 μm and spherical fused alumina having an average particle diameter (D₅₀) of 0.5 μm (weight ratio: 9:1)
(E) Additive: (E1) The compound represented by Formula 4, (E2) The compound represented by Formula 5, (E3) The compound represented by Formula 6, (E4) The compound represented by Formula 7
(F) Coupling agent
(F1) Methyltrimethoxysilane (SZ-6070, Dow Corning Corporation)
(F2) KBM-573 (N-phenyl-3-aminopropyltrimethoxysilane, Shinetsu Chemical Co., Ltd.)
(G) Carbon black (MA-600B, Mitsubishi Chemical Co., Ltd.)

### Examples 1 to 6 and Comparative Example 1

The aforementioned components were uniformly mixed in amounts shown in Table 1 (unit: parts by weight) in a Henschel mixer (KSM-22, KEUM SUNG MACHINERY Co., Ltd.) at a temperature of 25° C. to 30° C. for 30 minutes. Thereafter, the mixture was subjected to melt-kneading in a continuous kneader at a temperature of up to 110° C. for 30 minutes, cooled to a temperature of 10° C. to 15° C., and pulverized, thereby preparing an epoxy resin composition for encapsulation of semiconductor devices. In Table 1, “-” means that a corresponding component was not used.

Each of the epoxy resin compositions prepared in Examples 1 to 6 and Comparative Example 1 was evaluated as to the following properties. Results are shown in Table 1.
(1) Fluidity (spiral flow length): Using a low-pressure transfer molding machine, each of the prepared epoxy resin compositions was injected into a mold for measurement of fluidity under conditions of a mold temperature of 175° C., a load of 70 kgf/cm², an injection pressure of 9 MPa, and a curing time of 90 seconds in accordance with EMMI-1-66, followed by measurement of flow length. A greater flow length indicates better fluidity.
(2) Modulus: Using a transfer molding machine, a specimen (size: 20 mm×13 mm×1.6 mm (length×width×thickness)) was prepared by curing each of the prepared epoxy resin compositions under conditions of a mold temperature of 90° C.±5° C., an injection pressure of 1,000 psi±200 psi, and a curing time of 120 seconds. The specimen was subjected to post-curing in a hot air dryer at 90° C.±5° C. for 2 hours, followed by measurement of modulus of the specimen using a dynamic mechanical analyzer (DMA) (Q8000, TA Instruments Inc.). In measurement of modulus, the specimen was heated from −10° C. to 300° C. at a heating rate of 5° C./min, thereby obtaining storage modulus of the specimen at 25° C. and 260° C.
(3) Toughness: In accordance with ASTM D-790, a standard specimen (size: 125 mm×12.6 mm×6.4 mm (length×width×thickness) was prepared from each of the prepared epoxy resin compositions and was cured at 175° C. for 4 hours, followed by measurement of toughness of the specimen at 25° C. by a 3-point bending test using a Universal Testing Machine (UTM).
(4) Reliability: A semiconductor package manufactured using each of the prepared epoxy resin compositions was dried at 125° C. for 24 hours and then subjected to a thermal shock test of 5 cycles (1 cycle being defined as leaving the package at −65° C. for 10 minutes, at 25° C. for 10 minutes, and at 150° C. for 10 minutes). Thereafter, the presence of external cracks was observed under an optical microscope after pre-conditioning treatment in which a process of leaving the package at 85° C. and 60% RH for 168 hours, followed by IR reflow at 260° C. for 30 seconds was repeated three times.

TABLE 1

| | | Example | | | | | | Comparative |
|---|---|---|---|---|---|---|---|---|
| | | 1 | 2 | 3 | 4 | 5 | 6 | Example 1 |
| A | | 5.3 | 4.9 | 4.2 | 4.2 | 4.2 | 4.2 | 5.7 |
| B | | 4.5 | 4.2 | 3.4 | 3.4 | 3.4 | 3.4 | 4.9 |
| C | | 0.5 | 0.5 | 0.5 | 0.5 | 0.5 | 0.5 | 0.5 |
| D | | 88 | 88 | 88 | 88 | 88 | 88 | 88 |
| E | E1 | 0.8 | 1.5 | 3.0 | — | — | — | — |
| | E2 | — | — | — | 3.0 | — | — | — |
| | E3 | — | — | — | — | 3.0 | — | — |
| | E4 | — | — | — | — | — | 3.0 | — |
| F | F1 | 0.2 | 0.2 | 0.2 | 0.2 | 0.2 | 0.2 | 0.2 |
| | F2 | 0.2 | 0.2 | 0.2 | 0.2 | 0.2 | 0.2 | 0.2 |
| G | | 0.5 | 0.5 | 0.5 | 0.5 | 0.5 | 0.5 | 0.5 |
| Total | | 100 | 100 | 100 | 100 | 100 | 100 | 100 |
| Fluidity (inch) | | 58 | 58 | 56 | 57 | 55 | 54 | 57 |
| Modulus | @25° C. | 15.9 | 15.3 | 14.1 | 15.0 | 15.9 | 14.3 | 17.4 |
| | (GPa) | | | | | | | |
| | @260° C. | 643 | 573 | 476 | 520 | 630 | 499 | 974 |
| | (MPa) | | | | | | | |
| Toughness | | 0.71 | 0.90 | 1.12 | 0.98 | 0.73 | 1.01 | 0.49 |
| Reliability | External | 0 | 0 | 0 | 0 | 0 | 0 | 12 |
| | cracks | | | | | | | |
| | Number | 88 | 88 | 88 | 88 | 88 | 88 | 88 |
| | of tested | | | | | | | |
| | specimens | | | | | | | |

As can be seen from Table 1, the epoxy resin compositions of Examples 1 to 6 had good crack resistance due to high toughness thereof.

Conversely, the composition of Comparative Example 1, free from the at least one compound represented by Formula 1, suffered from cracking and thus failed to provide a reliable semiconductor device.

By way of summation and review, high-reliability epoxy molding compounds (EMCs) may help ensure better performance of semiconductors in use. Low-reliability EMCs may cause generation of external cracks on a semiconductor, rendering the semiconductor unusable. To improve the reliability of EMCs, it may be necessary to achieve high elasticity and high crack resistance through enhancement in toughness of an epoxy resin composition.

It may be an aspect of the present disclosure to provide an epoxy resin composition for encapsulation of semiconductor devices that may have high toughness and improved crack resistance.

Embodiments of the present disclosure may provide an epoxy resin composition for encapsulation of semiconductor devices that may have high toughness and thus improved crack resistance.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An epoxy resin composition for encapsulation of semiconductor devices,
the epoxy resin composition comprising:
an epoxy resin;
a curing agent;
an inorganic filler;
a curing catalyst; and
an additive including at least one compound represented by Formula 1: 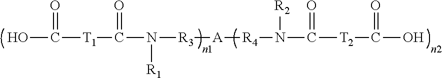
wherein A is a substituted or unsubstituted C₃ to C₂₀ cycloalkylene group or a substituted or unsubstituted C₆ to C₂₀ arylene group,
R₁ and R₂ are each independently hydrogen or a substituted or unsubstituted C₁ to C₅ alkyl group,
R₃ and R₄ are each independently a single bond or a substituted or unsubstituted C₁ to C₅ alkylene group,
T₁ and T₂ are each independently a substituted or unsubstituted C₁ to C₁₀ alkylene group, and
n1 and n2 are each independently an integer of greater than or equal to 1.

2. The epoxy resin composition as claimed in claim 1, wherein the at least one compound represented by Formula 1 is included in the epoxy resin composition in an amount of 0.5 wt % to 5 wt %, based on a total amount of the epoxy resin composition.

3. The epoxy resin composition as claimed in claim 1, wherein the additive including at least one compound represented by Formula 1 includes at least one compound represented by Formula 2 or Formula 3, 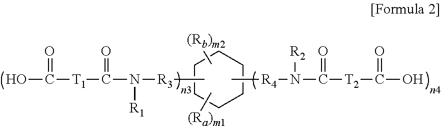
wherein each of R₁, R₂, R₃, R₄, T₁, and T₂ is defined the same as those of Formula 1,
Rₐ and R_{b} are each independently a substituted or unsubstituted C₁ to C₁₀ alkyl group or a substituted or unsubstituted C₆ to C₁₀ aryl group,
n3 and n4 are each independently an integer of greater than or equal to 1, and
m1 and m2 are each independently an integer of greater than or equal to 0, 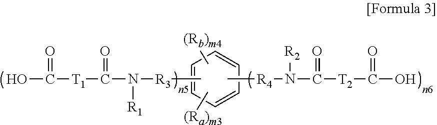
wherein each of R₁, R₂, R₃, R₄, T₁, and T₂ is defined the same as those of Formula 1,
Rₐ and R_{b} are each independently a substituted or unsubstituted C₁ to C₁₀ alkyl group or a substituted or unsubstituted C₆ to C₁₀ aryl group,
n5 and n6 are each independently an integer of greater than or equal to 1, and
m3 and m4 are each independently an integer of greater than or equal to 0.

4. The epoxy resin composition as claimed in claim 1, wherein the additive including at least one compound represented by Formula 1 includes at least one compound represented by Formula 4 to Formula 7,

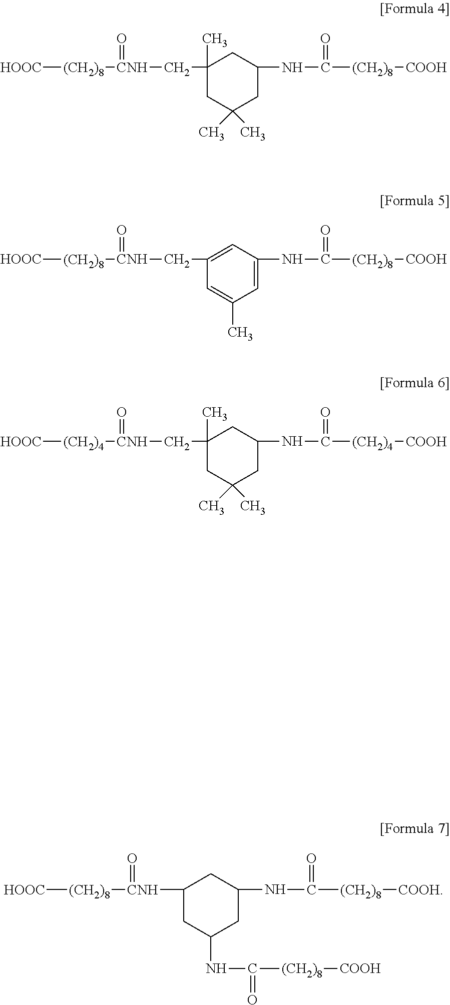

5. The epoxy resin composition as claimed in claim 1, wherein the epoxy resin composition includes, based on a total weight of the epoxy resin composition,
2 wt % to 17 wt % of the epoxy resin;
0.5 wt % to 13 wt % of the curing agent;
50 wt % to 95 wt % of the inorganic filler;
0.5 wt % to 5 wt % of the at least one compound represented by Formula 1; and
0.01 wt % to 5 wt % of the curing catalyst.

6. A semiconductor device encapsulated using the epoxy resin composition for encapsulation of semiconductor devices as claimed in claim 1.

7. The semiconductor device as claimed in claim 6, wherein the at least one compound represented by Formula 1 is included in the epoxy resin composition in an amount of 0.5 wt % to 5 wt %, based on a total amount of the epoxy resin composition.

8. The semiconductor device as claimed in claim 6, wherein the additive including at least one compound represented by Formula 1 includes at least one compound represented by Formula 2 or Formula 3, 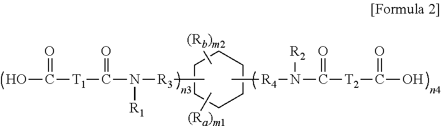
wherein each of R₁, R₂, R₃, R₄, T₁, and T₂ is defined the same as those of Formula 1,
Rₐ and R_{b} are each independently a substituted or unsubstituted C₁ to C₁₀ alkyl group or a substituted or unsubstituted C₆ to C₁₀ aryl group,
n3 and n4 are each independently an integer of greater than or equal to 1, and
m1 and m2 are each independently an integer of greater than or equal to 0, 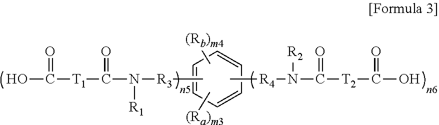
wherein each of R₁, R₂, R₃, R₄, T₁, and T₂ is defined the same as those of Formula 1,
Rₐ and R_{b} are each independently a substituted or unsubstituted C₁ to C₁₀ alkyl group or a substituted or unsubstituted C₆ to C₁₀ aryl group,
n5 and n6 are each independently an integer of greater than or equal to 1, and
m3 and m4 are each independently an integer of greater than or equal to 0.

9. The semiconductor device as claimed in claim 6, wherein the additive including at least one compound represented by Formula 1 includes at least one compound represented by Formula 4 to Formula 7,

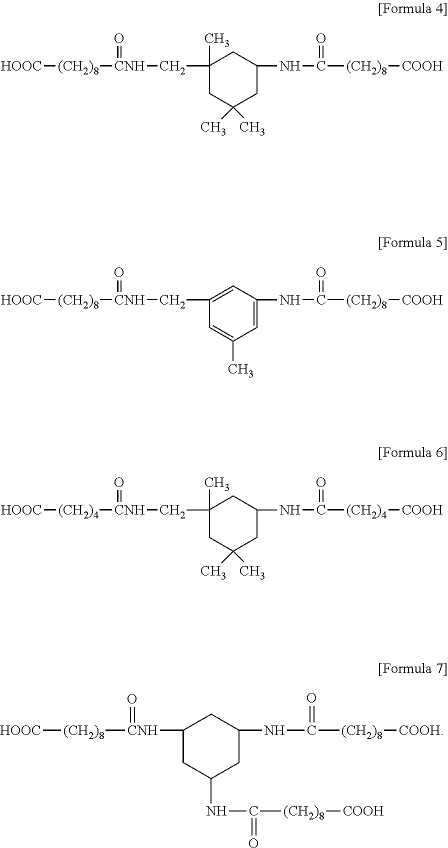

10. The semiconductor device as claimed in claim 6, wherein the epoxy resin composition includes, based on a total weight of the epoxy resin composition,
2 wt % to 17 wt % of the epoxy resin;
0.5 wt % to 13 wt % of the curing agent;
50 wt % to 95 wt % of the inorganic filler;
0.5 wt % to 5 wt % of the at least one compound represented by Formula 1; and
0.01 wt % to 5 wt % of the curing catalyst.
